(19) United States
(12) Patent Application Publication
(10) Pub. No.: US 2026/0247052 A1
(43) Pub. Date: Aug. 20, 2026

(54) PHOTODETECTOR AND ELECTRONIC APPARATUS

(71) Applicant: SONY SEMICONDUCTOR SOLUTIONS CORPORATION, KANAGAWA (JP)

(72) Inventor: YOSHIAKI TASHIRO, KANAGAWA (JP)

(21) Appl. No.: 19/164,539

(22) PCT Filed: Feb. 16, 2024
(86) PCT No.: PCT/JP2024/005545

§ 371 Date: Sep. 11, 2025

(30) Foreign Application Priority Data
Mar. 28, 2023 (JP) 2023-051791

(51) Int. Cl. H04N 25/78; H04N 25/772; H04N 25/778

(52) U.S. Cl. CPC H04N 25/78; H04N 25/772; H04N 25/778

(57) ABSTRACT

A photodetector according to an embodiment of the present disclosure includes a plurality of pixel units each including a photoelectric conversion layer configured to output a photocurrent by photoelectric conversion, a readout circuit configured to output a first signal based on a first photocurrent outputted by the photoelectric conversion layer, and an AD conversion circuit configured to output a second signal based on a second photocurrent outputted by the photoelectric conversion layer.

### TECHNICAL FIELD

The present disclosure relates to a photodetector and an electronic apparatus.

### BACKGROUND ART

A device that has a stacked structure in which an element substrate and a readout circuit substrate are stacked and photoelectrically converts entering light is proposed (PTL 1).

### CITATION LIST

### Patent Literature

PTL 1: Japanese Unexamined Patent Application Publication No. 2021-89978

### SUMMARY OF THE INVENTION

A device that detects light is expected to have improved performance.

It is desired to provide a photodetector having a satisfactory performance.

A photodetector according to an embodiment of the present disclosure includes a plurality of pixel units, the plurality of pixel units each including: a photoelectric conversion layer configured to output a photocurrent by photoelectric conversion, a readout circuit configured to output a first signal based on a first photocurrent, the first photocurrent being outputted by the photoelectric conversion layer, and an AD conversion circuit configured to output a second signal based on a second photocurrent, the second photocurrent being outputted by the photoelectric conversion layer.

An electronic apparatus according to an embodiment of the present disclosure includes an optical system and a photodetector that receives light transmitted through the optical system. The photodetector includes a plurality of pixel units, the plurality of pixel units each including a photoelectric conversion layer configured to output a photocurrent by photoelectric conversion, a readout circuit configured to output a first signal based on a first photocurrent, the first photocurrent being outputted by the photoelectric conversion layer, and an AD conversion circuit configured to output a second signal based on a second photocurrent, the second photocurrent being outputted by the photoelectric conversion layer.

### BRIEF DESCRIPTION OF THE DRAWINGS

FIG. 1 is a diagram illustrating an example of a schematic configuration of a pixel unit in a photodetector according to a first embodiment of the present disclosure.

FIG. 2 is a diagram describing an example of a signal generated by the photodetector according to the first embodiment of the present disclosure.

FIG. 3 is a diagram illustrating a configuration example of the pixel unit in the photodetector according to the first embodiment of the present disclosure.

FIG. 4 is a diagram illustrating an example of a cross-sectional configuration of the photodetector according to the first embodiment of the present disclosure.

FIG. 5 is a diagram describing a layout example of the pixel unit in the photodetector according to the first embodiment of the present disclosure.

FIG. 6 is a diagram describing a layout example of the pixel unit in the photodetector according to the first embodiment of the present disclosure.

FIG. 7 is a diagram illustrating a configuration example of a pixel unit in the photodetector according to a second embodiment of the present disclosure.

FIG. 8 is a diagram describing a layout example of the pixel unit in the photodetector according to the second embodiment of the present disclosure.

FIG. 9 is a diagram describing a layout example of the pixel unit in the photodetector according to the second embodiment of the present disclosure.

FIG. 10 is a diagram describing a configuration example of a pixel unit in a photodetector according to modification example 1 of the present disclosure.

FIG. 11 is a diagram describing another configuration example of the pixel unit in the photodetector according to modification example 1 of the present disclosure.

FIG. 12 is a diagram describing a configuration example of a pixel unit in a photodetector according to modification example 2 of the present disclosure.

FIG. 13 is a diagram describing another configuration example of the pixel unit in the photodetector according to modification example 2 of the present disclosure.

FIG. 14 is a block diagram depicting an example of schematic configuration of a vehicle control system.

FIG. 15 is a diagram of assistance in explaining an example of installation positions of an outside-vehicle information detecting section and an imaging section.

FIG. 16 is a view depicting an example of a schematic configuration of an endoscopic surgery system.

FIG. 17 is a block diagram depicting an example of a functional configuration of a camera head and a camera control unit (CCU).

### MODES FOR CARRYING OUT THE INVENTION

In the following, some embodiments of the present disclosure are described in detail with reference to the drawings. It is to be noted that the description is given in the following order.
1. First Embodiment
2. Second Embodiment
3. Modification Examples
4. Usage Examples
5. Practical Application Examples

### 1. First Embodiment

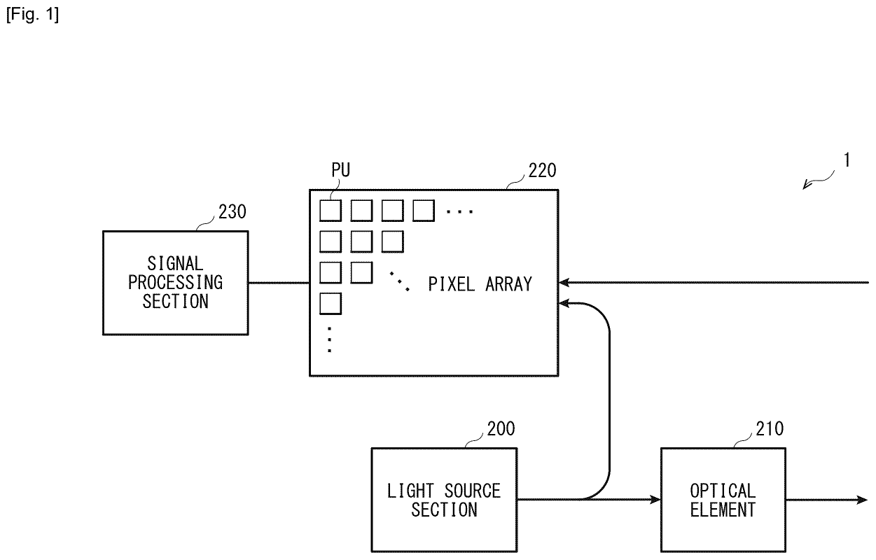

FIG. 1 is a diagram illustrating an example of a schematic configuration of a photodetector according to a first embodiment of the present disclosure. The photodetector 1 is a device that enables detection of entering light. The photodetector 1 includes a plurality of pixels each having a photoelectric conversion section (photoelectric conversion element). For example, the photoelectric conversion section of each pixel is a photodiode (PD) and is configured to photoelectrically convert light. The photodetector 1 makes it possible to receive light transmitted through an optical system including an optical lens (not illustrated) and to generate a signal. The photodetector 1 includes a plurality of pixel units PU each including a plurality of pixels, and is configured to generate a signal by photoelectrically converting entering light. The photodetector 1 includes a region (a pixel array 220) in which the plurality of pixel units PU is arranged two-dimensionally. For example, the pixel array 220 includes a plurality of pixel units PU arranged in a matrix, and it can also be said that the pixel array 220 is a light receiving region.

The photodetector 1 is a device that enables distance measurement, and is configured to perform distance measurement using, for example, an FMCW (Frequency Modulated Continuous Wave) method. The photodetector 1 makes it possible to transmit and receive, via the optical system, an optical signal that is to be a modulated light having a modulated frequency, and to measure a distance to a measurement target, a speed of the measurement target, or the like. For example, the photodetector 1 is applicable as an FMCW-LiDAR (Light Detection and Ranging).

As one example, the photodetector 1 detects, for each pixel unit PU, a distance to an object (a subject) that is a measurement target and generates image data (distance image data) related to the distance to the object. For example, it is possible for the photodetector 1 to generate a depth map (Depth Map).

In addition, the photodetector 1 is configured to capture an image of the subject. The photodetector 1 takes in entering light (image light) from the subject via the optical system including an optical lens. It is possible for the photodetector 1 to capture the image of the subject formed by the optical system. The photodetector 1 is also applicable to various electronic apparatuses having an imaging function, such as a digital still camera, a video camera, or a mobile phone.

As one example, the photodetector 1 generates image data related to the image of the subject using a signal outputted from each pixel unit PU. It is possible for the photodetector 1 to generate image data indicating a gray scale value of each pixel. For example, the photodetector 1 is configured to generate a short-wave infrared image (an SWIR image).

For example, the photodetector 1 includes a photonic integrated circuit (PIC: Photonic Integrated Circuit). It is possible to manufacture the photodetector 1 using a substrate including silicon (a silicon substrate, an SOI (Silicon On Insulator) substrate, or the like.), utilizing silicon photonics technology. For example, the photodetector 1 has a structure (a stacked structure) in which a plurality of substrates is stacked.

As illustrated in FIG. 1, the photodetector 1 includes a light source section 200, an optical element 210, a pixel array 220, and a signal processing section 230. The photodetector 1 makes it possible to cause the light source section 200 and the optical element 210 or the like to irradiate a measurement target with an optical signal having a modulated frequency (laser light), and to receive the optical signal reflected and delayed from the measurement target.

For example, in the photodetector 1, a reference light branched (separated) from the light outputted from the light source section 200 and a reflected light (returned light) reflected from the measurement target enter (are inputted to) the pixel array 220, and an electric signal having a frequency corresponding to a difference between a frequency of the reference light and that of the reflected light is detected. The electric signal generated by receiving the reflected light from the measurement target is a signal corresponding to the distance to the measurement target.

For example, the pixel array 220, the optical element 210, the signal processing section 230, or the like are provided separately on a plurality of substrates. The light source section 200 may be mounted on the photodetector 1 or may be provided outside the photodetector 1. It is to be noted that the pixel array 220, the signal processing section 230, or the like may be provided on one substrate. The photodetector 1 may be configured as a light detecting system including the light source section 200, the optical element 210, the pixel array 220, the signal processing section 230, or the like.

The light source section 200 illustrated in FIG. 1 is configured to generate an optical signal. For example, the light source section 200 includes a light emitting element and is configured to output an optical signal (laser light). As one example, the light source section 200 includes a variable laser light source and is configured to emit light to the measurement target. The light source section 200 may include a modulation section configured to modulate a frequency of the optical signal.

The light source section 200 may include, as the modulation section, a modulator (Modulator) configured using, for example, a Mach-Zehnder interferometer (Mach-Zehnder Interferometer). It is possible for the light source section 200 to generate laser light having a modulated frequency and to emit the laser light having the modulated frequency. In other words, the light source section 200 makes it possible to generate and output a signal (chirp signal) having a frequency that changes continuously over time.

The light source section 200 outputs, to the optical element 210, the output light that is to be the optical signal having a modulated frequency. In the photodetector 1, for example, the output light from the light source section 200 is branched (separated) by a splitter. A portion of the output light from the light source section 200 is transmitted to the optical element 210 side, and another portion of the output light from the light source section 200 is transmitted to the pixel array 220 side as a reference light (local light). For example, a reference light having 50% of the power (light intensity) of the output light from the light source section 200 is divided from the output light from the light source section 200 and inputted to (entering) the pixel array 220.

The optical element 210 is configured to output the optical signal transmitted from the light source section 200. The optical signal (laser light) having a modulated frequency is propagated to the optical element 210. It is possible for the optical element 210 to output the optical signal that is the laser light having a modulated frequency to an outside as output light (irradiation light). The optical element 210 is an antenna configured to transmit an optical signal, and makes it possible to irradiate the measurement target with the laser light having a modulated frequency.

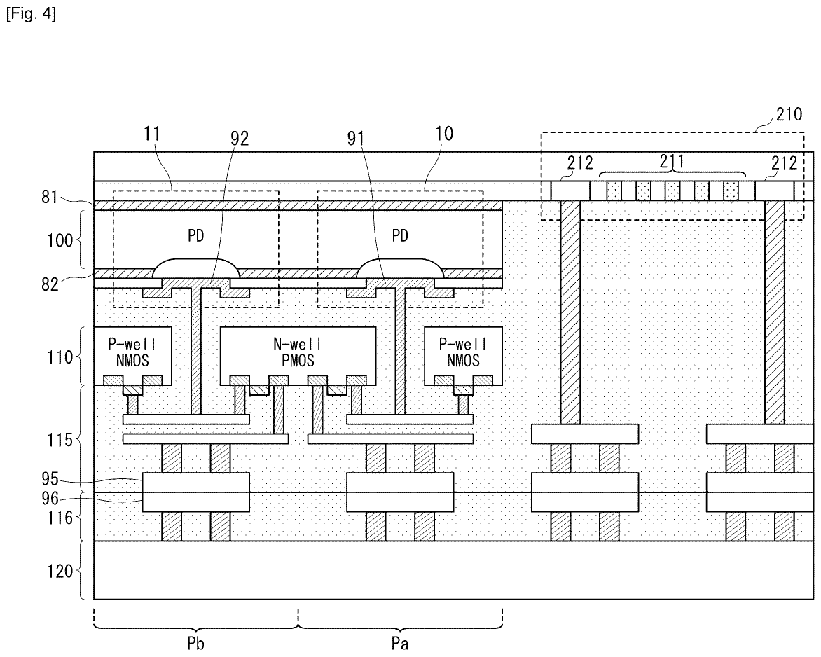

As described below (see FIG. 4), the optical element 210 includes a plurality of diffraction gratings 211 and a plurality of heaters 212. A heater 212 is provided adjacent to the diffraction gratings 211 and is configured to heat each diffraction grating 211. As a result of the diffraction grating 211 being heated by the heater 212, a refractive index of the diffraction grating 211 is changed, thereby changing a traveling direction of the optical signal emitted from the diffraction grating 211. In the photodetector 1, it becomes possible to perform scanning (a scan) on the laser light that is the optical signal by temperature control or the like using the heater 212.

The pixel array 220 includes a plurality of pixel units PU. The pixel units PU each include a photoelectric conversion section and is configured to detect entering light. Each pixel unit PU is configured to receive a reference light from the light source section 200 and a reflected light from an object as a measurement target, to generate an electric signal, and to output the electric signal as a signal related to the distance to the object (referred to as a distance measurement signal).

For example, the pixel unit PU includes a balanced photodiode and is configured to convert an optical signal into an electric signal. The pixel unit PU is configured to generate the distance measurement signal that is based on the optical signal from the light source section 200 and the optical signal reflected from the object.

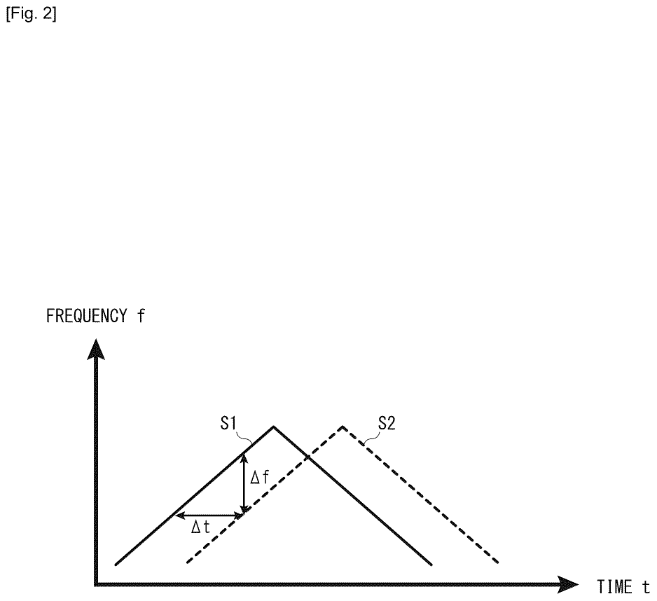

FIG. 2 is a diagram describing an example of a signal generated by the photodetector according to the first embodiment. In FIG. 2, a vertical axis indicates a frequency of the optical signal that is a chirp signal, and a horizontal axis indicates time. FIG. 2 illustrates an optical signal S1 that is a transmission light to the measurement target, and an optical signal S2 that is a reception light from the measurement target.

The distance measurement signal generated in the pixel unit PU is a signal (also referred to as a beat signal) having a frequency corresponding to a difference between the frequency of the optical signal S1 and the frequency of the optical signal S2. The pixel unit PU includes an AD conversion circuit (an AD conversion section) and allows outputting, to the signal processing section 230, the distance measurement signal converted into a digital signal by the AD conversion circuit. In the photodetector 1, it is possible to calculate the distance to the measurement target, the speed of the measurement target, or the like, using the distance measurement signal.

In addition, the pixel unit PU is configured to generate an electric signal based on an amount of light received from an object, and to output the electric signal as a signal (referred to as an imaging signal) related to the image of the object (the subject). The imaging signal is a signal related to a gray scale value. It is possible for each pixel unit PU disposed in the pixel array 220 to generate and output a distance measurement signal and an imaging signal to the signal processing section 230.

The signal processing section 230 is a signal processing circuit and is configured to perform signal processing. The signal processing section 230 includes a circuit that performs various types of signal processing on the signal outputted from the pixel unit PU. The signal processing section 230 includes a calculation circuit, a memory circuit, or the like. The signal processing section 230 may include a processor and a memory.

The signal processing section 230 analyzes a frequency (a beat frequency) of the distance measurement signal outputted from each pixel unit PU in the pixel array 220, thereby making it possible to calculate a distance between the photodetector 1 and the measurement target. In addition, the signal processing section 230 makes it possible to calculate a speed (a relative speed) of the measurement target using a Doppler shift of light.

As one example, the signal processing section 230 calculates the speed of the measurement target on the basis of the beat frequency in a case where the frequency of the laser light is increased over time, that is, in the case of an up-chirp, and on the basis of the beat frequency in a case where the frequency of the laser light is decreased over time, that is, in the case of a down-chirp.

For example, the signal processing section 230 makes it possible to emit a laser light that is an optical signal having a modulated frequency in a form of a triangular wave and to calculate the speed of the measurement target, the distance to the measurement target, or the like by using the beat frequency of the beat signal in each case of the up-chirp and the down-chirp occurring in succession. For example, the signal processing section 230 calculates the distance between the photodetector 1 and the measurement target, or the like using the beat frequency obtained by fast Fourier transform (FFT) processing.

The signal processing section 230 is configured to perform signal processing such as AD (Analog Digital) conversion and CDS (Correlated Double Sampling) on the imaging signal outputted from each pixel unit PU. In addition, the signal processing section 230 makes it possible to perform various signal processing such as noise reduction processing, interpolation processing, or gray scale correction processing on the imaging signal of each pixel unit PU.

As described above, it is possible for the signal processing section 230 to perform signal processing on the distance measurement signal of each pixel unit PU and to generate the distance image data representing the distance to the subject. In addition, the signal processing section 230 makes it possible to perform signal processing on the imaging signal of each pixel unit PU, and to generate image data representing the image of the subject.

In addition, the signal processing section 230 is configured to perform processing of synthesizing the imaging signal and the distance measurement signal for each pixel unit PU. As one example, the signal processing section 230 performs processing of adding the distance to the subject detected for each pixel unit PU to the image data representing the image of the subject. For example, the signal processing section 230 makes it possible to generate, as a signal value (a pixel value) of each pixel during a frame period, image data including gray scale information and distance information regarding each pixel.

The signal processing section 230 is also a control section and is configured to control each section of the photodetector 1. It is possible for the signal processing section 230 to include a circuit such as a PLL (Phase Locked Loop) or a DAC (Digital to Analog Converter). For example, the signal processing section 230 is configured to supply a signal controlling the light source section 200 to the light source section 200. In addition, the signal processing section 230 is configured to control scanning of the optical signal by the optical element 210, generation and processing of the distance measurement signal and the imaging signal by the pixel unit PU, or the like.

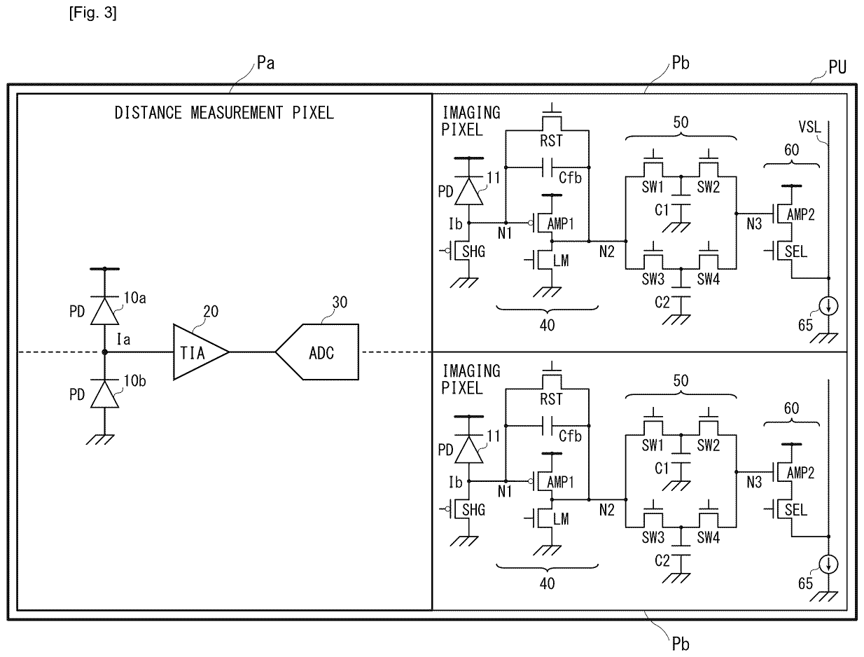

FIG. 3 is a diagram illustrating a configuration example of a pixel unit in the photodetector according to the first embodiment. The pixel unit PU includes a pixel that allows outputting a distance measurement signal (referred to as a distance measurement pixel Pa) and a pixel that allows outputting an imaging signal (referred to as an imaging pixel Pb). In the example illustrated in FIG. 3, the pixel unit PU includes one distance measurement pixel Pa and two imaging pixels Pb. It is to be noted that the number and arrangement of the distance measurement pixel Pa and the imaging pixel Pb in the pixel unit PU are not limited to those in the example illustrated in the figure and are modifiable as appropriate.

The distance measurement pixel Pa includes a photoelectric conversion section 10 (the photoelectric conversion section 10a and the photoelectric conversion section 10b in FIG. 3). It can also be said that the distance measurement pixel Pa includes a pixel in which the photoelectric conversion section 10a is provided and a pixel in which the photoelectric conversion section 10b is provided. The distance measurement pixel Pa has a size equivalent to two pixels. In the example illustrated in FIG. 3, the pixel unit PU includes one distance measurement pixel Pa and two imaging pixels Pb, and has a region of 2×2 pixels.

The distance measurement pixel Pa includes the photoelectric conversion section 10 (the photoelectric conversion section 10a and the photoelectric conversion section 10b in FIG. 3), an amplification circuit 20, and an AD conversion circuit 30, and is configured to detect entering light. The photoelectric conversion section 10a and the photoelectric conversion section 10b are each configured to receive light and generate a signal. The photoelectric conversion sections 10a and 10b are each a light receiving section (a light receiving element) and configured to generate an electric charge by photoelectric conversion.

For example, the photoelectric conversion sections 10a and 10b are each a photodiode (PD) and convert entering light into an electric charge. In the example illustrated in FIG. 3, the photoelectric conversion sections 10a and 10b are a balanced photodiode and are electrically coupled in series with each other.

The photoelectric conversion section 10a and the photoelectric conversion section 10b each make it possible to receive light, generate an electric charge by photoelectric conversion, and output a photocurrent. One of the photoelectric conversion sections 10a and 10b, for example, the photoelectric conversion section 10b, is configured to receive the reference light from the light source section 200 described above. Another of the photoelectric conversion section 10a and the photoelectric conversion section 10b, for example, the photoelectric conversion section 10a, is configured to receive the reflected light from the measurement target.

The distance measurement pixel Pa is configured to output, by the photoelectric conversion section 10a and the photoelectric conversion section 10b, a distance measurement signal based on the optical signal that is the reference light from the light source section 200 and the reflected light that is the optical signal reflected from the object. For example, in response to a reception of the reference light and the reflected light, a signal corresponding to a photocurrent Ia outputted by the photoelectric conversion section 10a and the photoelectric conversion section 10b is generated and outputted as a distance measurement signal.

The amplification circuit 20 is configured to generate a signal based on the photocurrent outputted by the photoelectric conversion section 10. In the example illustrated in FIG. 3, the amplification circuit 20 is provided with respect to the photoelectric conversion section 10a and the photoelectric conversion section 10b. The amplification circuit 20 is configured to output a signal based on the photocurrent Ia generated by the photoelectric conversion sections 10a and 10b.

For example, the amplification circuit 20 (an amplifying section) includes a transimpedance amplifier (TIA: Transimpedance Amplifier) and is configured to convert a current signal into a voltage signal. In the example illustrated in FIG. 3, the amplification circuit 20 includes a TIA circuit and is electrically coupled to a node that couples the photoelectric conversion section 10a and the photoelectric conversion section 10b.

The amplification circuit 20 makes it possible to convert the current signal generated by the photoelectric conversion section 10a and the photoelectric conversion section 10b into a voltage signal, and to output the distance measurement signal that is the voltage signal to the AD conversion circuit 30. The distance measurement signal has a frequency corresponding to a frequency difference between the optical signal that is the output light from the light source section 200 and the optical signal that is the reflected light from the measurement target.

The AD conversion circuit 30 is configured to convert an inputted analog signal into a digital signal. The AD conversion circuit 30 is an ADC (Analog to Digital Converter). In the pixel array 220, it is possible to provide the amplification circuit 20 and the AD conversion circuit 30 for each distance measurement pixel Pa including the photoelectric conversion section 10a and the photoelectric conversion section 10b.

In the example illustrated in FIG. 3, the distance measurement signal is inputted to the AD conversion circuit 30 (the AD conversion section) from the amplification circuit 20. The AD conversion circuit 30 performs sampling on the distance measurement signal and converts the distance measurement signal that is an analogue signal into a digital signal. The AD conversion circuit 30 makes it possible to output, to the signal processing section 230, the distance measurement signal converted into a digital signal at each sampling point.

The imaging pixel Pb includes a photoelectric conversion section 11, a transistor SHG, an amplification circuit 40, a memory circuit 50, and a readout circuit 60, and is configured to detect entering light. The imaging pixel Pb includes a node N1 to which the photoelectric conversion section 11 and the transistor SHG are coupled, a node N2 to which the amplification circuit 40 and the memory circuit 50 are coupled, and a node N3 to which the memory circuit 50 and the readout circuit 60 are coupled.

The photoelectric conversion section 11 is configured to receive light and generate a signal. The photoelectric conversion section 11 is a light receiving section (a light receiving element) and is configured to generate an electric charge by photoelectric conversion. It is possible for the photoelectric conversion section 11 to receive light, generate an electric charge by photoelectric conversion, and output a photocurrent Ib. In the example illustrated in FIG. 3, the photoelectric conversion section 11 is a photodiode (PD). The photoelectric conversion section 11 performs photoelectric conversion and generate an electric charge in accordance with the amount of light received.

The transistor SHG is configured to reset the electric charge of the photoelectric conversion section 11. In the example illustrated in FIG. 3, the transistor SHG is electrically coupled to the reference potential line and is configured to reset the photoelectric conversion section 11. In the example illustrated in FIG. 3, the reference potential line is an earthing line (a ground line). The transistor SHG allows the electric charge accumulated in the photoelectric conversion section 11 to be reset, thus resetting the voltage of the photoelectric conversion section 11. For example, the transistor SHG includes a PMOS transistor.

The amplification circuit 40 is configured to generate a signal based on the photocurrent outputted by the photoelectric conversion section 11. For example, the amplification circuit 40 (the amplifying section) includes a TIA circuit. The amplification circuit 40 is configured to output a signal based on the photocurrent Ib generated by the photoelectric conversion section 11.

In the example illustrated in FIG. 3, the amplification circuit 40 includes a transistor AMP1, a transistor LM, a transistor RST, and a capacitor Cfb. For example, the transistor AMP1 includes a PMOS transistor, and the transistor LM includes an NMOS transistor.

The transistor AMP1 has a gate coupled to the node N1. The transistor AMP1 has a source electrically coupled to the power supply line to which the supply voltage is supplied. The transistor LM is electrically coupled in series with the transistor AMP1. The transistor LM makes it possible to generate an electric current in accordance with the signal level of the signal inputted to the gate and to supply the generated electric current to the transistor AMP1.

The capacitor Cfb is provided between the node N1 that is to be an input section of the amplification circuit 40 and the node N2 that is to be an output section of the amplification circuit 40. The capacitor Cfb has a predetermined capacitance value and is configured to hold a voltage. One electrode of the capacitor Cfb is coupled to the node N1. Another electrode of the capacitor Cfb is coupled to the node N2. For example, the capacitor Cfb includes a MOS capacitance, a MIM (Metal-Insulator-Metal) capacitance, or the like.

The transistor RST is provided between the node N1 that is the input section of the amplification circuit 40 and the node N2 that is the output section of the amplification circuit 40, and is configured to electrically couple the input section and the output section of the amplification circuit 40. For example, the transistor RST includes an NMOS transistor.

The amplification circuit 40 is configured to convert a current signal into a voltage signal. The amplification circuit 40 is a TIA circuit configured using the capacitor Cfb and is referred to as a CTIA (Capacitive Trans Impedance Amplifier) circuit. It is to be noted that the amplification circuit 40 and the memory circuit 50 together can also be referred to as a CTIA circuit. The amplification circuit 40 converts the current signal generated by the photoelectric conversion section 11 into a voltage signal. The amplification circuit 40 makes it possible to generate a voltage signal in accordance with the amount of light received in the photoelectric conversion section 11, and to output the voltage signal to the memory circuit 50.

The memory circuit 50 is configured to hold the signal based on the photocurrent outputted by the photoelectric conversion section 11. In the example illustrated in FIG. 3, the memory circuit 50 includes a switch SW1 to SW4, a capacitor C1, and a capacitor C2. The memory circuit 50 is configured to hold a signal generated by the amplification circuit 40 on the basis of the photocurrent Ib of the photoelectric conversion section 11, that is, a voltage signal corresponding to the amount of light received in the photoelectric conversion section 11.

The switch SW1 is provided between the output section of the amplification circuit 40 and the capacitor C1, and is configured to electrically couple the output section of the amplification circuit 40 and the capacitor C1. In addition, the switch SW2 is provided between the capacitor C1 and the readout circuit 60, and is configured to electrically couple the capacitor C1 and the readout circuit 60.

The switch SW3 is provided between the output section of the amplification circuit 40 and the capacitor C2, and is configured to electrically couple the output section of the amplification circuit 40 and the capacitor C2. In addition, the switch SW4 is provided between the capacitor C2 and the readout circuit 60, and is configured to electrically couple the capacitor C2 and the readout circuit 60.

Each switch (the switch SW1, SW2, SW3, or SW4) of the memory circuit 50 includes a transistor. For example, each of the switch SW1, the switch SW2, the switch SW3, and the switch SW4 includes an NMOS transistor.

The capacitors C1 and C2 are each configured to hold a voltage. For example, the capacitors C1 and C2 each include a MOS capacitance, an MIM capacitance, or the like. It is to be noted that the transistor SHG described above allows the electric charge accumulated in each of the capacitors C1 and C2 to be discharged via the transistor RST.

The transistor SHG allows the electric charge accumulated in the capacitor C1 to be reset via the transistor RST and the switch SW1, thus resetting the voltage of the capacitor C1. In addition, the transistor SHG allows the electric charge accumulated in the capacitor C2 to be reset via the transistor RST and the switch SW3, thus resetting the voltage of the capacitor C2.

The readout circuit 60 is configured to output a signal based on the photocurrent outputted by the photoelectric conversion section 11. In the example illustrated in FIG. 3, the readout circuit 60 includes a transistor AMP2 and a transistor SEL. The transistor AMP2 is configured to generate and output a signal based on the voltage held in the memory circuit 50.

As illustrated in FIG. 3, the transistor AMP2 has a gate electrically coupled to the memory circuit 50. To the gate of the transistor AMP2, the voltage signal converted by the amplification circuit 40 and the memory circuit 50 on the basis of the photocurrent Ib of the photoelectric conversion section 11 is inputted. The transistor AMP2 has a drain coupled to the power supply line to which the power supply voltage is supplied, and the AMP2 has a source coupled to the signal line VSL via the transistor SEL.

The transistor AMP2 has a source electrically coupled with a current source 65 provided with respect to the signal line VSL. The current source 65 is configured to supply an electric current to the transistor AMP2. For example, the current source 65 is included in a source follower circuit together with the transistor AMP2.

The transistor AMP2 is configured to generate a signal based on the voltage held in the memory circuit 50, that is, a signal based on the voltage held in the capacitor C1 or the capacitor C2, and to output the signal to the signal line VSL. It is to be noted that the readout circuit 60 may include the current source 65.

The transistor SEL is configured to control an output of the pixel signal. The transistor SEL is configured to output the signal from the transistor AMP2 to the signal line VSL. The transistor SEL makes it possible to control an output timing of the signal of the imaging pixel Pb.

For example, the transistor SHG, the transistor RST, the transistor SEL, the switches SW1 to SW4 or the like of the imaging pixel Pb are controlled to be turned on and off by the signal processing section 230 of the photodetector 1. The signal processing section 230 controls each switch of the transistor SHG, the transistor RST, the transistor SEL, and the memory circuit 50, thereby causing a signal to be outputted from the imaging pixel Pb to the signal line VSL.

For example, when the transistor SHG, the transistor RST, and the switch SW3 are turned on (into a conductive state), the node N1, the node N2, and the capacitor C2 are electrically coupled together, to reset the electric charge accumulated in the imaging pixel Pb. In a case where the switch SW4 is turned on, the transistor AMP2 and the transistor SEL output, as a signal Sp, a signal corresponding to the voltage held in the capacitor C2 to the signal line VSL. The signal Sp becomes a signal indicating a reset level (a reference level).

In a case where the transistor SHG and the transistor RST are turned off (into a non-conductive state) and the switch SW1 is turned on, the node N2 and the capacitor C1 are electrically coupled together, to cause the amplification circuit 40 to supply the capacitor C1 with the voltage corresponding to the photocurrent Ib generated by the photoelectric conversion section 11.

During a charge accumulation period (an exposure period), the voltage corresponding to the amount of light received in the photoelectric conversion section 11 is inputted to the capacitor C1 and held therein. When the switch SW2 is turned on, the voltage held in the capacitor C1 is inputted to the transistor AMP2. The transistor AMP2 and the transistor SEL output, as a signal Sd, a signal corresponding to the voltage held in the capacitor C1 to the signal line VSL. The signal Sd is an imaging signal based on the amount of light received from the measurement target.

The signal outputted from each imaging pixel Pb is inputted to the signal processing section 230 via the signal line VSL. The signal processing section 230 performs signal processing such as AD conversion or correlated double sampling on the signal Sd and the signal Sp of the imaging pixel Pb. As one example, the signal processing section 230 makes it possible to perform CDS processing to subtract the signal Sp from the signal Sd, and to obtain an imaging signal after the CDS processing.

Controlling the transistor SHG in each pixel unit PU in the pixel array 220 allows the signal processing section 230 to reset the photoelectric conversion section 11 in all imaging pixels Pb simultaneously. The photodetector 1 makes it possible to align an imaging timing in each imaging pixel Pb, thus enabling global shutter performance.

As described above, the photodetector 1 according to the present embodiment includes the pixel unit PU configured to output an imaging signal and a distance measurement signal. This makes it possible for the photodetector 1 to obtain an imaging signal and a distance measurement signal, and to generate the image data of the subject and the distance image data. For example, it becomes possible to obtain an infrared image of the subject, distance data and speed data of the measurement target, or the like.

Providing the pixel unit PU including the distance measurement pixel Pa and the imaging pixel Pb makes it possible to generate a distance measurement signal and an imaging signal using a common optical system. Compared with a case where the pixel for distance measurement and the pixel for imaging are provided in separate devices and separate optical systems are used, it is possible to reduce a processing load in the case of signal synthesis processing.

The photodetector 1 makes it possible to generate a distance measurement signal and an imaging signal using a common optical system, thus suppressing an increase in the load of signal synthesis between the imaging signal and the distance measurement signal (for example, the load of processing to associate gray scale information with distance information). It becomes possible to prevent a complication in an algorithm, a decrease in signal accuracy, an increase in signal processing time, or the like.

In the photodetector 1 according to the present embodiment, a plurality of pixel units PU is provided repeatedly in an entire surface of the pixel array 220. This makes it possible to obtain an imaging signal and a distance measurement signal from an entire surface of the pixel array 220, thus making it possible to perform a measurement of the object with high accuracy.

In addition, the distance measurement pixel Pa and the imaging pixel Pb in each pixel unit PU include, respectively, the amplification circuit 20 and the amplification circuit 40 each of which enables amplification of a signal. This makes it possible to increase a sensitivity to entering light, and to increase an accuracy of light detection. It becomes possible to improve image quality.

Furthermore, in the present embodiment, the distance measurement pixel Pa has a region equivalent to two pixels as described above. In the distance measurement pixel Pa, it is possible to secure a region in which the AD conversion circuit 30 is to be disposed. This makes it possible to increase the resolution of the AD conversion circuit, that is, the number of bits of AD conversion, and to improve the accuracy of the AD conversion of the distance measurement signal. Thus, it becomes possible to measure the distance to the measurement target, the speed of the measurement target, or the like with high accuracy.

FIG. 4 is a diagram illustrating an example of a cross-sectional configuration of the photodetector according to the first embodiment. As illustrated in FIG. 4, the photodetector 1 includes a photoelectric conversion layer 100, a semiconductor layer 110, a wiring layer 115, a wiring layer 116, and a semiconductor layer 120. The photodetector 1 has a configuration in which the photoelectric conversion layer 100, the semiconductor layer 110, the wiring layer 115, the wiring layer 116, and the semiconductor layer 120 are stacked.

In the photoelectric conversion layer 100, the photoelectric conversion section 10 (the photoelectric conversion section 10a and the photoelectric conversion section 10b) of each distance measurement pixel Pa and the photoelectric conversion section 11 of each imaging pixel Pb described above are provided. For example, the photoelectric conversion layer 100 includes InGaAs. The photoelectric conversion layer 100 may include another compound semiconductor material. The photoelectric conversion layer 100 may include germanium (Ge), silicon germanium (SiGe), or the like or may include another material. The photoelectric conversion layer 100 may include a quantum dot.

The photoelectric conversion section 10 and the photoelectric conversion section 11 each include the photoelectric conversion layer 100, a protective film 81, and a protective film 82. The protective film 81 and the protective film 82 are each a passivation film (a protective layer) and each include, for example, InP. It is to be noted that the protective film 81 and the protective film 82 may be formed using a compound semiconductor material, such as an InP-based material, a GaAs-based material, or an SiGe-based material, or may be configured using another material.

The protective film 81 and the protective film 82 are disposed to sandwich the photoelectric conversion layer 100. The protective film 81 and the protective film 82 are provided to be opposed to each other to sandwich the photoelectric conversion layer 100. In the example illustrated in FIG. 4, the protective film 81 is a protective film in an upper portion of the photoelectric conversion layer 100, and the protective film 82 is a protective film in a lower portion of the photoelectric conversion layer 100. It is to be noted that the photoelectric conversion layer 100 and the protective films 81 and 82 together can also be referred to as the photoelectric conversion layer 100.

For example, the semiconductor layer 110 and the semiconductor layer 120 are each a silicon layer including silicon. The semiconductor layer 110 and the semiconductor layer 120 may include another semiconductor material. It is to be noted that the semiconductor layer 110 and the wiring layer 115 together can also be referred to as the semiconductor layer 110 (or the silicon layer). In addition, the semiconductor layer 120 and the wiring layer 116 together can also be referred to as the semiconductor layer 120 (or the silicon layer).

For example, the wiring layer 115 and the wiring layer 116 each include a conductor film and an insulating film and have a plurality of wires and vias (VIA) or the like. For example, the wiring layer 115 and the wiring layer 116 include two or more wiring layers. Each of the wiring layer 115 and the wiring layer 116 has a configuration in which a plurality of wirings is stacked with an insulating film in between. It can also be said that this insulating film is an interlayer insulating film (an interlayer insulating layer).

The wiring of each of the wiring layers 115 and 116 is formed, for example, using a metallic material such as aluminum (Al), copper (Cu), tungsten (W), or the like. The wiring in the wiring layers 115 and 116 may be configured using polysilicon (Poly-Si) or another conductive material. The interlayer insulating film is formed using, for example, silicon oxide (SiO), silicon nitride (SiN), silicon oxynitride (SiON), or the like.

For example, in the semiconductor layer 110 and the wiring layer 115, the amplification circuit 20, the transistor SHG, the amplification circuit 40, or the like described above are provided. For example, as schematically illustrated in FIG. 4, an element such as a transistor including a source region, a drain region, a gate electrode, or the like is formed on a side of one surface of the semiconductor layer 110.

In addition, for example, in the semiconductor layer 120 and the wiring layer 116, the AD conversion circuit 30, the memory circuit 50, and the readout circuit 60 described above are provided. It is to be noted that it is possible, for example, to provide the signal processing section 230 described above in the semiconductor layer 120 and the wiring layer 116.

In the semiconductor layer 110 and the wiring layer 115, an electrode 91 and an electrode 92 are provided. The electrode 91 is a contact and electrically couples the photoelectric conversion section 10 and a circuit provided in the semiconductor layer 110. For example, the photoelectric conversion section 10 is electrically coupled via the electrode 91 to the amplification circuit 20 provided in the semiconductor layer 110 and the wiring layer 115.

The electrode 92 is a contact and electrically couples the photoelectric conversion section 11 and a circuit provided in the semiconductor layer 110. For example, the photoelectric conversion section 11 is electrically coupled to the amplification circuit 40 provided in the semiconductor layer 110 and the wiring layer 115 via the electrode 92.

In addition, the electrode 95 is provided in the wiring layer 115, and the electrode 96 is provided in the wiring layer 116. For example, the electrodes 95 and 96 are each an electrode formed using copper (Cu). The electrode 95 and the electrode 96 are each an electrode used for bonding between metal electrodes, and it can also be said that the electrode 95 and the electrode 96 are a bonding electrode.

The electrode 95 and the electrode 96 electrically couple the circuit of the semiconductor layer 110 and the circuit of the semiconductor layer 120. It is to be noted that the electrodes 95 and 96 may include, for example, a metallic material other than copper, such as nickel (Ni), cobalt (Co), gold (Au), or the like. In addition, the semiconductor layer 110 and the semiconductor layer 120 may be stacked using a bump.

In addition, as illustrated in FIG. 4, the photodetector 1 includes the optical element 210 described above. In the photodetector 1, for example, a plurality of optical elements 210 is formed to be located above the photoelectric conversion layer 100. The optical element 210 includes the diffraction grating 211 and the heater 212.

As one example, the optical element 210 includes the diffraction grating 211 having a plurality of circular holes that is periodically present. The heater 212 is disposed for each diffraction grating 211 or for each plurality of diffraction gratings 211, and is provided, for example, at an end of the diffraction grating 211. For example, the diffraction grating 211 and the heater 212 include a semiconductor region having the same conductivity type.

For example, as in the example illustrated in FIG. 4, the heater 212 is electrically coupled to the circuit in the semiconductor layer 120 through a via or the like, and is configured to energize the diffraction grating 211. The heater 212 applies heat to the diffraction grating 211 by supplying an electric current, thereby making it possible to change the refractive index of the diffraction grating 211 and to change the direction of the optical signal emitted from the diffraction grating 211.

As described above, in the photodetector 1 according to the present embodiment, the photoelectric conversion section 10 of the distance measurement pixel Pa and the photoelectric conversion section 11 of the imaging pixel Pb are provided in the same photoelectric conversion layer 100. This makes it possible to generate a distance measurement signal and an imaging signal using a common optical system, thereby making it possible to reduce the load on the signal synthesis processing.

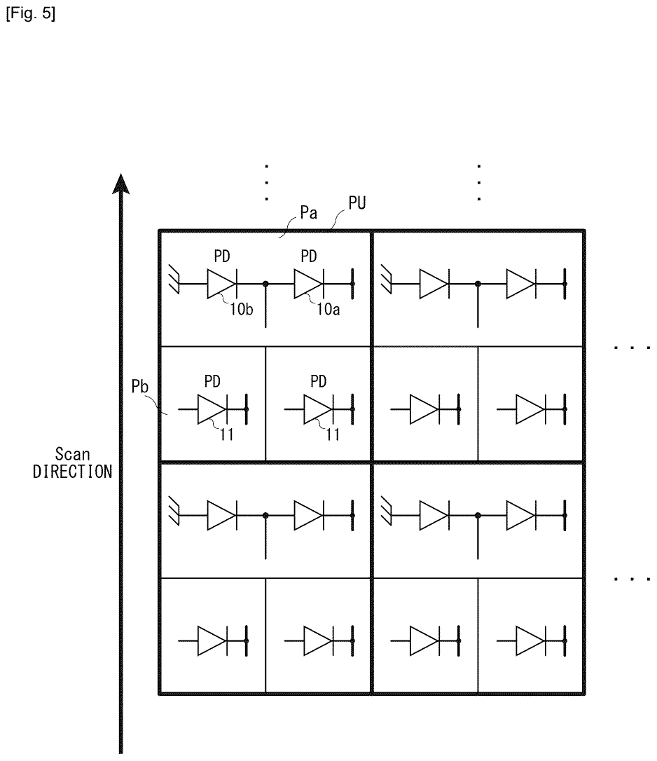

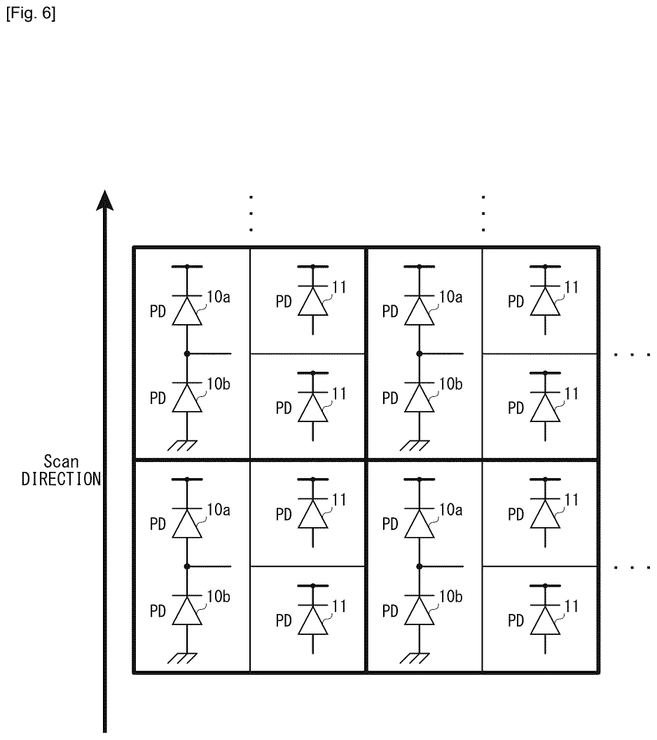

FIGS. 5 and 6 are a diagram describing a layout example of the pixel unit in the imaging device according to the first embodiment. As one example, as illustrated in FIG. 5, the pixel unit PU may be disposed to be perpendicular to a scan direction of the laser light that is the optical signal outputted by the light source section 200 and the optical element 210.

In addition, as another example, as illustrated in FIG. 6, the pixel unit PU may be disposed to be horizontal to the scan direction of the laser light that is an optical signal. It is to be noted that the placement of the pixel unit PU is not limited to the example illustrated in the figure and is modifiable as appropriate.

### Workings and Effects

A photodetector according to the present embodiment includes a plurality of pixel units (the pixel unit PU) each including a photoelectric conversion layer (the photoelectric conversion layer 100) configured to output a photocurrent by photoelectric conversion, a readout circuit (the readout circuit 60) configured to output a first signal based on a first photocurrent (for example, the photocurrent of the photoelectric conversion section 11) outputted by the photoelectric conversion layer, and an AD conversion circuit (the AD conversion circuit 30) configured to output a second signal based on a second photocurrent (for example, the photocurrent of the photoelectric conversion section 10) outputted by the photoelectric conversion layer.

In the photodetector 1 according to the present embodiment, a plurality of pixel units PU each including the readout circuit 60 configured to output an imaging signal and the AD conversion circuit 30 configured to output a distance measurement signal is provided. This enables the photodetector 1 to obtain an imaging signal and a distance measurement signal from each pixel unit PU. It becomes possible to achieve a photodetector having high detection performance.

### 2. Second Embodiment

Next, a second embodiment of the present disclosure is described. In the following, components similar to those in the above embodiments are denoted by the same numerical references and descriptions thereof are omitted as appropriate.

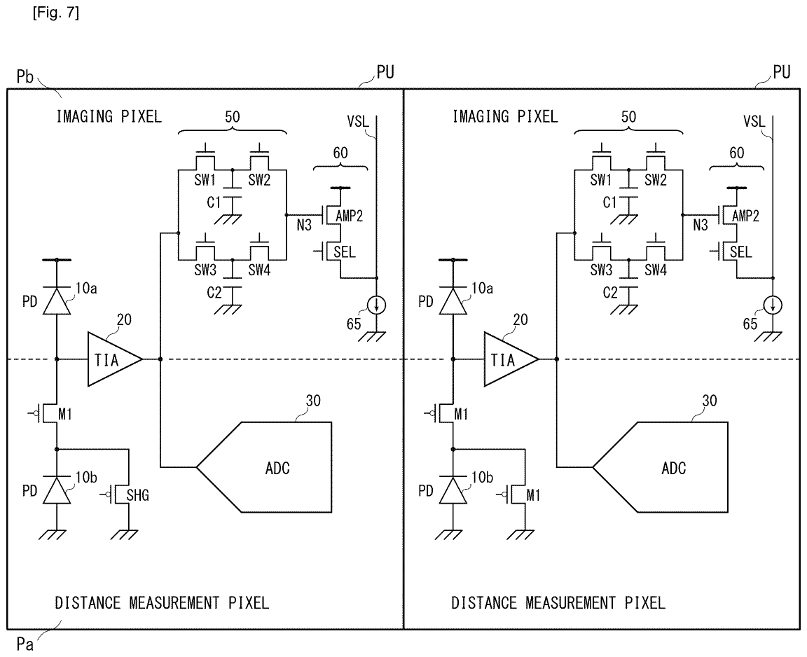

FIG. 7 is a diagram illustrating a configuration example of a pixel unit in a photodetector according to the second embodiment of the present disclosure. The pixel unit PU has a configuration in which the distance measurement pixel Pa and the imaging pixel Pb share the amplification circuit 20. The pixel unit PU includes one distance measurement pixel Pa and one imaging pixel Pb, and has a size equivalent to two pixels.

In addition, the pixel unit PU includes a transistor M1. The transistor M1 is configured to electrically couple the photoelectric conversion section 10a and the photoelectric conversion section 10b. For example, the transistor M1 includes a PMOS transistor. The transistor SHG is electrically coupled to a node that couples the photoelectric conversion section 10b and the transistor M1. It is to be noted that the transistor SHG may be omitted as necessary.

For the amplification circuit 20, it is possible to generate an imaging signal that is a voltage signal based on the photocurrent outputted by the photoelectric conversion section 10a, and to output the imaging signal to the memory circuit 50. In addition, the amplification circuit 20 makes it possible to generate a distance measurement signal that is a voltage signal based on the photocurrent outputted by the photoelectric conversion section 10a and the photoelectric conversion section 10b, and to output the distance measurement signal to the AD conversion circuit 30.

For the signal processing section 230 of the photodetector 1, it is possible to supply the transistor M1 with a signal that controls the transistor M1, and to control the transistor M1 to be turned on and off. In a case where the transistor M1 is in an off state, the amplification circuit 20 makes it possible to generate an imaging signal that is the voltage signal based on the photocurrent generated by the photoelectric conversion section 10a, and to output the imaging signal to the memory circuit 50. It is possible to read out, via the memory circuit 50 and the readout circuit 60, the imaging signal that is based on the photocurrent outputted by the photoelectric conversion section 10a.

In a case where the transistor M1 is in an on state, the photoelectric conversion section 10a and the photoelectric conversion section 10b are electrically coupled together. The amplification circuit 20 makes it possible to generate a distance measurement signal that is based on the photocurrent generated by the photoelectric conversion sections 10a and 10b included in a balanced photodiode, and to output the distance measurement signal to the AD conversion circuit 30. It is possible to read out the distance measurement signal based on the photocurrent outputted by the photoelectric conversion sections 10a and 10b via the AD conversion circuit 30.

Thus, for the signal processing section 230, it is possible to control the transistor M1, the memory circuit 50, the readout circuit 60, the AD conversion circuit 30, or the like, and to read out the imaging signal and the distance measurement signal. For example, the signal processing section 230 may switch a state of the transistor M1 on a frame-by-frame basis to read out the imaging signal and the distance measurement signal.

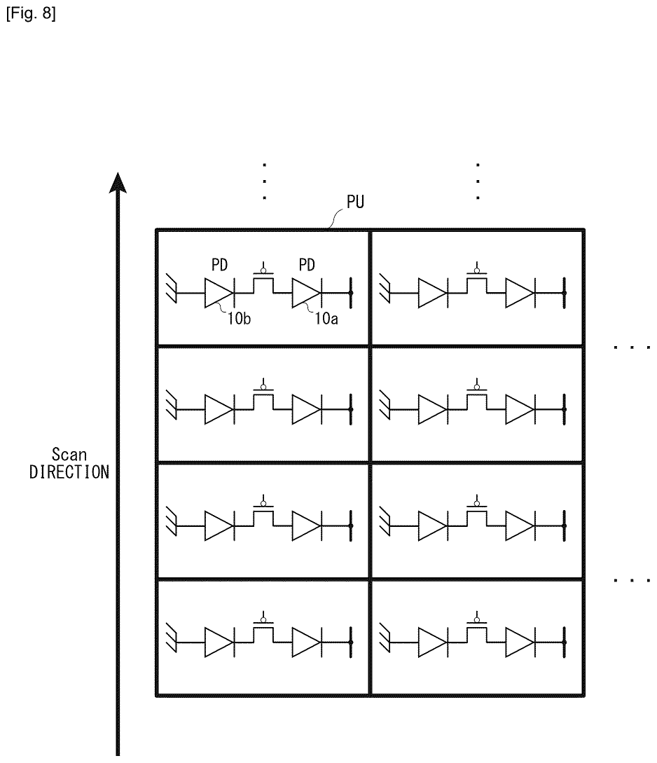

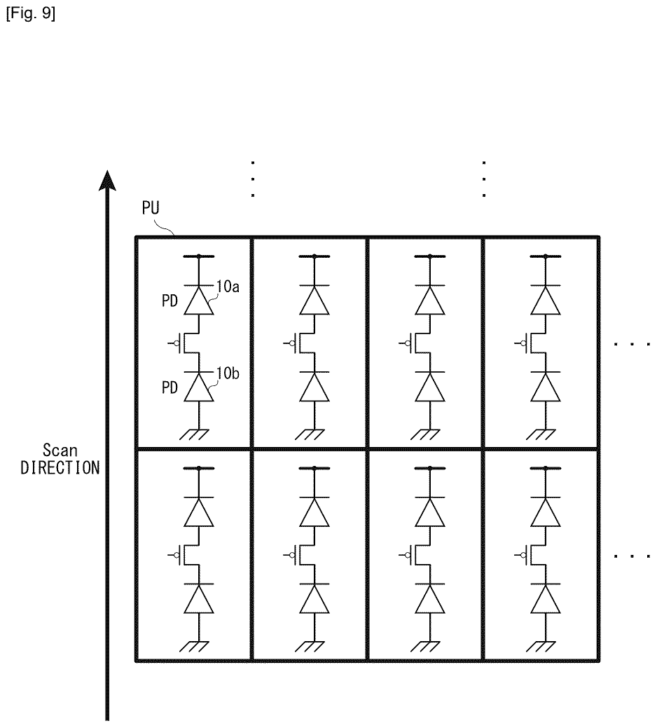

FIGS. 8 and 9 are a diagram describing a layout example of a pixel unit in the imaging device according to the second embodiment. As one example, as illustrated in FIG. 8, the pixel unit PU may be disposed to be perpendicular to the scan direction of the laser light that is an optical signal outputted by the light source section 200 and the optical element 210.

In addition, as another example, as illustrated in FIG. 9, the pixel unit PU may be disposed to be horizontal to the scan direction of the laser light that is an optical signal. It is to be noted that the placement of pixel unit PU is not limited to the example illustrated in the figure and is modifiable as necessary.

### Workings and Effects

The photodetector according to the present embodiment includes a plurality of pixel units (the pixel unit PU) each including a photoelectric conversion layer (the photoelectric conversion layer 100) configured to output a photocurrent by photoelectric conversion, a readout circuit (the readout circuit 60) configured to output a first signal based on a first photocurrent (for example, the photocurrent of the photoelectric conversion section 10a) outputted by the photoelectric conversion layer, and an AD conversion circuit (the AD conversion circuit 30) configured to output a second signal based on a second photocurrent (for example, the photocurrent of the photoelectric conversion section 10b) outputted by the photoelectric conversion layer.

The photodetector 1 according to the present embodiment includes a plurality of pixel units PU each including the readout circuit 60 configured to output an imaging signal and the AD conversion circuit 30 configured to output a distance measurement signal. In the case of the present embodiment, it is also possible for the photodetector 1 to obtain the imaging signal and the distance measurement signal for each pixel unit PU. It becomes possible to achieve a photodetector having high detection performance.

Next, modification examples of the present disclosure are described. In the following, components similar to those in the above embodiments are denoted by the same reference numerals, and descriptions thereof are omitted as appropriate.

### 3. Modification Examples

### 3-1. Modification Example 1

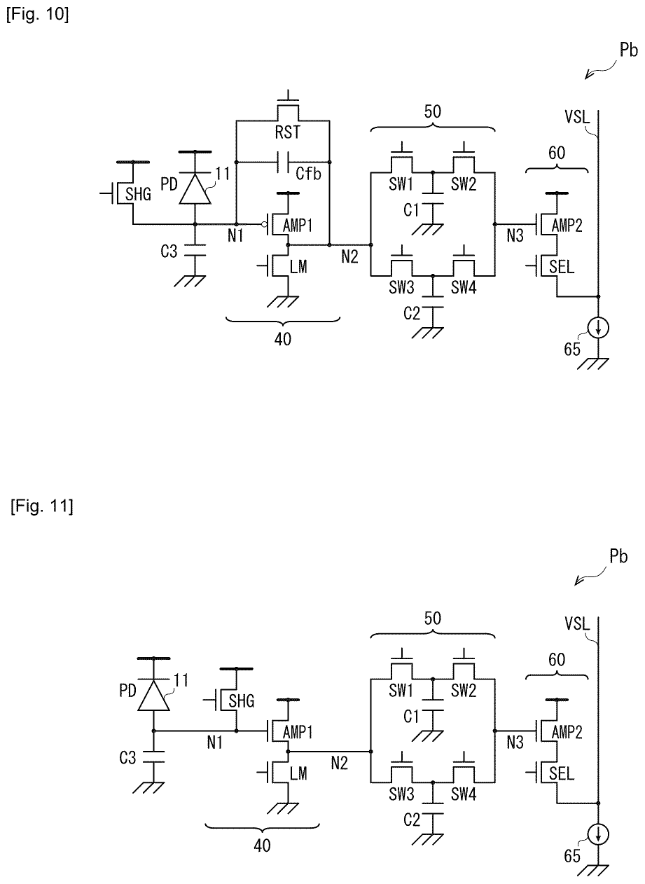

In the embodiments described above, some configuration examples of the pixel unit PU have been described, but these are only illustrative, and the configuration of the pixel unit PU is not limited to the examples described above. FIG. 10 is a diagram describing a configuration example of a pixel unit in a photodetector according to modification example 1 of the present disclosure. For example, as in the example illustrated in FIG. 10, the imaging pixel Pb may include a capacitor C3.

For the capacitor C3, it is possible to accumulate the electric charge photoelectrically converted by the photoelectric conversion section 11. It can also be said that the capacitor C3 is a holding section that allows holding an electric charge. For example, it is possible for the capacitor C3 to include a capacitance added to the node N1. The capacitor C3 and the amplification circuit 40 make it possible to convert the photocurrent outputted by the photoelectric conversion section 11 into a voltage signal.

As in the example illustrated in FIG. 11, the transistor AMP1 of the amplification circuit 40 may be configured using an NMOS transistor. In the example illustrated in FIG. 11, the transistor AMP1 has a source electrically coupled with the transistor LM. The transistor LM is included in the source follower circuit together with transistor AMP1.

### 3-2. Modification Example 2

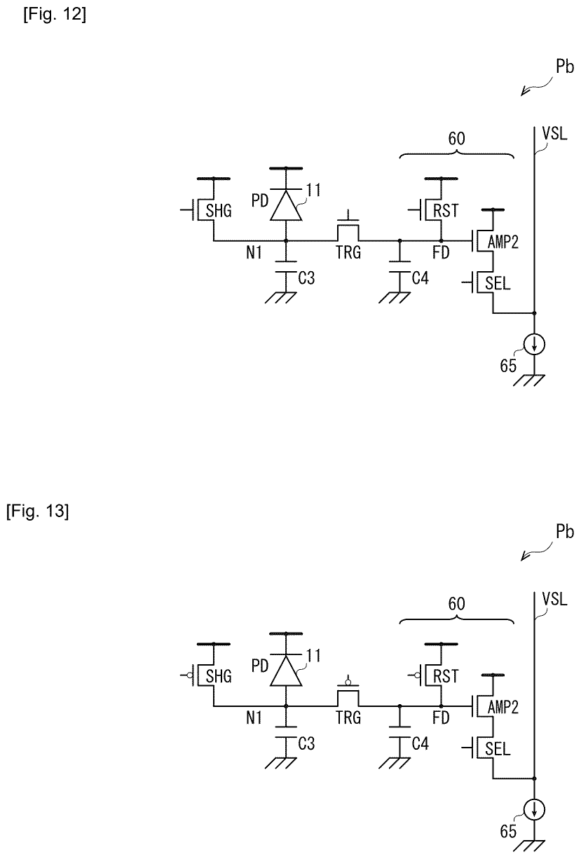

FIGS. 12 and 13 are a diagram describing a configuration example of a pixel unit in a photodetector according to modification example 2. As in the example illustrated in FIG. 12, the imaging pixel Pb of the pixel unit PU may include a transistor TRG and a floating diffusion FD. The transistor TRG is configured to electrically couple the photoelectric conversion section 11 and the transistor AMP2. It is to be noted that the transistor TRG may include, for example, a PMOS transistor, as in the example illustrated in FIG. 13.

The floating diffusion FD is an accumulation section and is configured to accumulate the transferred electric charge. The floating diffusion FD makes it possible to accumulate the electric charge photoelectrically converted by the photoelectric conversion section 11. The floating diffusion FD allows the transferred electric charge to be accumulated and converted into a voltage corresponding to a capacitance C4 of the floating diffusion FD.

### 4. Usage Examples

For example, the photodetector described above is usable in a variety of cases of sensing light, including visible light, infrared light, ultraviolet light, and X-rays, as follows.
Apparatuses that shoot images for appreciation, including digital cameras and mobile equipment having a camera function
Apparatuses for traffic use, including onboard sensors that shoot images of the front, back, surroundings, inside, and so on of an automobile for safe driving such as automatic stop and for recognition of a driver's state, monitoring cameras that monitor traveling vehicles and roads, and distance measurement sensors that measure distances including a vehicle-to-vehicle distance
Apparatuses for use in home electrical appliances including televisions, refrigerators, and air-conditioners to shoot images of a user's gesture and bring the appliances into operation in accordance with the gesture
Apparatuses for medical treatment and health care use, including endoscopes and apparatuses that shoot images of blood vessels by receiving infrared light
Apparatuses for security use, including monitoring cameras for crime prevention and cameras for individual authentication
Apparatuses for beauty care use, including skin measuring apparatuses that shoot images of skin and microscopes that shoot images of scalp
Apparatuses for sports use, including action cameras and wearable cameras for sports applications and the like
Apparatuses for agricultural use, including cameras for monitoring the states of fields and crops

### 5. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

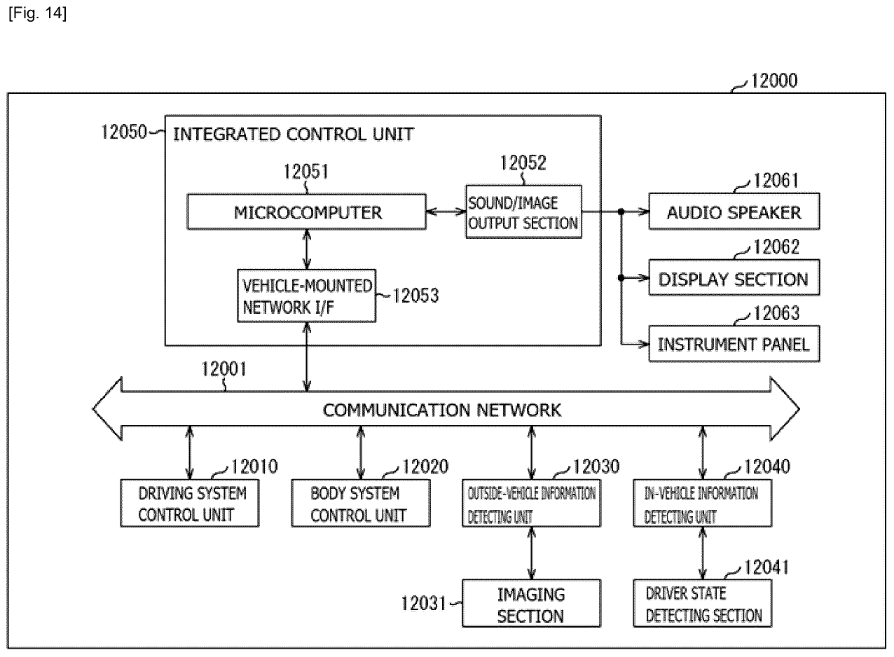

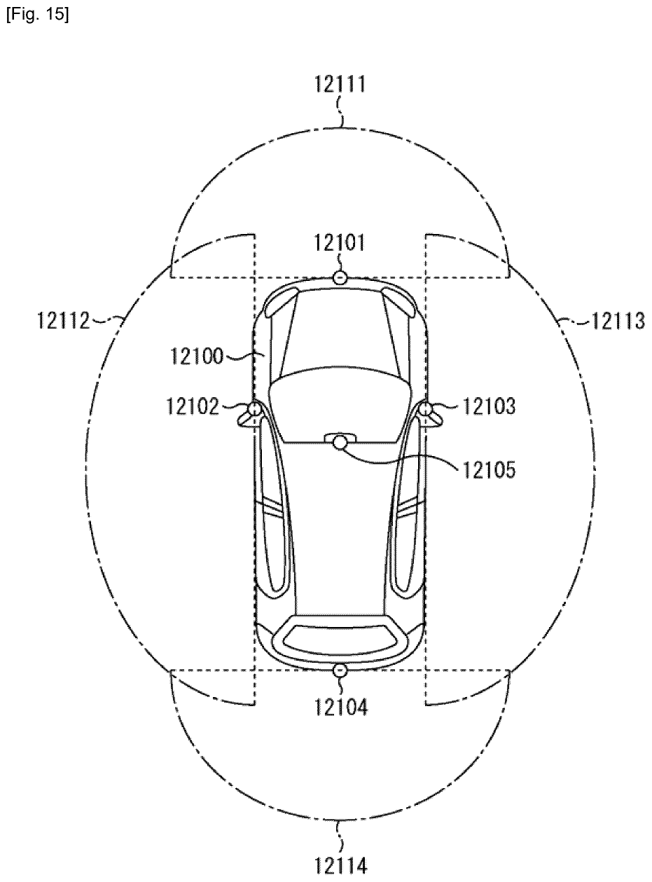

FIG. 14 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up display.

FIG. 15 is a diagram depicting an example of the installation position of the imaging section 12031.

In FIG. 15, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 15 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the photodetector 1 or the like can be applied to the imaging section 12031. Applying the technology according to an embodiment of the present disclosure to the imaging section 12031 enables obtainment of a photographed image having high definition. This makes it possible to perform highly accurate control utilizing the photographed image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

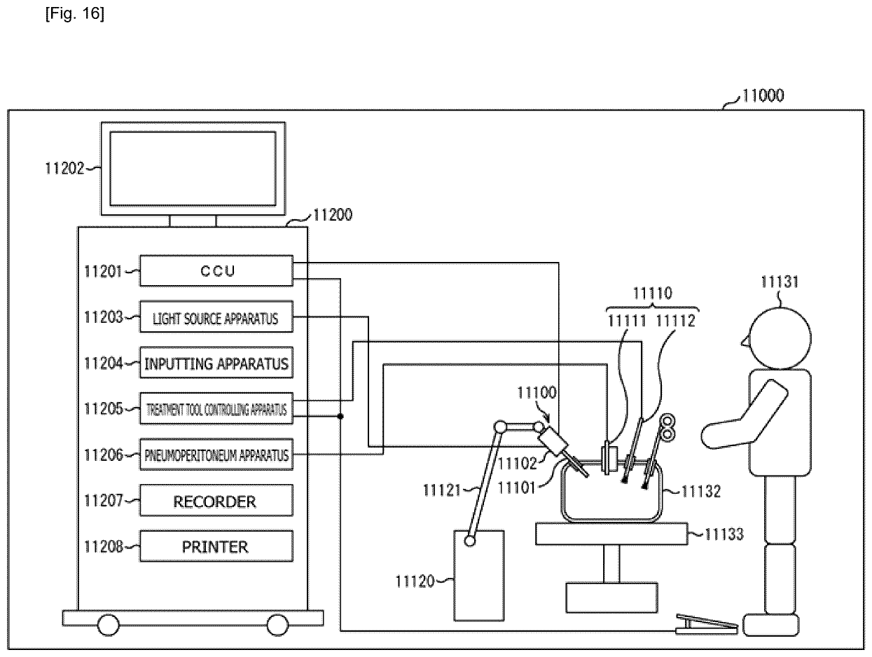

FIG. 16 is a view depicting an example of a schematic configuration of an endoscopic surgery system to which the technology according to an embodiment of the present disclosure (present technology) can be applied.

In FIG. 16, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

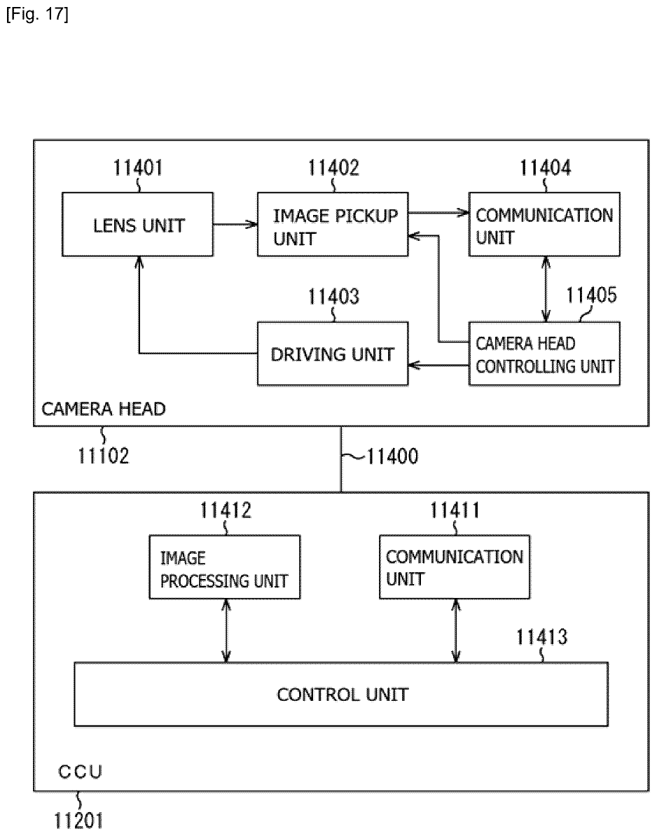

FIG. 17 is a block diagram depicting an example of a functional configuration of the camera head 11102 and the CCU 11201 depicted in FIG. 16.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 makes it possible to provide the endoscope 11100 having high definition.

Although the description has been given hereinabove of the present disclosure with reference to the embodiment, the modification examples, the usage example, and the practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate.

A photodetector according to an embodiment of the present disclosure includes a plurality of pixel units each including a photoelectric conversion layer configured to output a photocurrent by photoelectric conversion, a readout circuit configured to output a first signal based on a first photocurrent outputted by the photoelectric conversion layer, and an AD conversion circuit configured to output a second signal based on a second photocurrent outputted by the photoelectric conversion layer. This enables the photodetector to obtain an imaging signal and a distance measurement signal from each pixel unit PU. It becomes possible to achieve a photodetector having favorable performance.

It is to be noted that the effects described herein are merely exemplary and are not limited to the description, and may further include other effects. In addition, the present disclosure may also have the following configurations.
(1)

A photodetector including a plurality of pixel units, the plurality of pixel units each including

a photoelectric conversion layer configured to output a photocurrent by photoelectric conversion,

a readout circuit configured to output a first signal based on a first photocurrent, the first photocurrent being outputted by the photoelectric conversion layer, and

an AD conversion circuit configured to output a second signal based on a second photocurrent, the second photocurrent being outputted by the photoelectric conversion layer.
(2)

The photodetector according to (1), in which

the readout circuit is configured to output the first signal related to a gray scale value, and

the AD conversion circuit is configured to output the second signal related to a distance to an object.
(3)

The photodetector according to (1) or (2), in which the pixel units each include a first amplification circuit and a second amplification circuit, the first amplification circuit being configured to generate a voltage signal based on the first photocurrent, the second amplification circuit being configured to generate a voltage signal based on the second photocurrent.
(4)

The photodetector according to (3), in which

the readout circuit is configured to output the first signal based on the voltage signal generated by the first amplification circuit, and

the AD conversion circuit is configured to convert the voltage signal generated by the second amplification circuit into a digital signal, and to output the digital signal as the second signal.
(5)

The photodetector according to (3) or (4), in which

the pixel units each include a first photoelectric conversion element and a second photoelectric conversion element, the first photoelectric conversion element and the second photoelectric conversion element being provided in the photoelectric conversion layer,

the first photoelectric conversion element and the second photoelectric conversion element are electrically coupled in series between a power supply line and a reference potential line, and

the second amplification circuit is configured to generate the voltage signal based on the second photocurrent, the second photocurrent being outputted by the first photoelectric conversion element and the second photoelectric conversion element.
(6)

The photodetector according to any one of (3) to (5), in which

the pixel units each include a third photoelectric conversion element provided in the photoelectric conversion layer, and

the first amplification circuit is configured to generate the voltage signal based on the first photocurrent outputted by the third photoelectric conversion element.
(7)

The photodetector according to any one of (1) to (6), in which the pixel units each include an amplification circuit, the amplification circuit being configured to generate a voltage signal based on the first photocurrent and a voltage signal based on the second photocurrent.
(8)

The photodetector according to (7), in which

the readout circuit is configured to output the first signal on a basis of the voltage signal based on the first photocurrent, the first photocurrent being generated by the amplification circuit, and

the AD conversion circuit is configured to output the second signal on a basis of the voltage signal based on the second photocurrent, the second photocurrent being generated by the amplification circuit.
(9)

The photodetector according to (7) or (8), in which

the pixel units each include a first photoelectric conversion element, a second photoelectric conversion element, and a transistor, the first photoelectric conversion element and the second photoelectric conversion element being provided in the photoelectric conversion layer, the transistor being coupled between the first photoelectric conversion element and the second photoelectric conversion element, and

the first photoelectric conversion element and the second photoelectric conversion element are electrically coupled in series between a power supply line and a reference potential line via the transistor.
(10)

The photodetector according to (9), in which the amplification circuit is configured to generate the voltage signal based on the second photocurrent while the transistor is in an on state, the second photocurrent being outputted by the first photoelectric conversion element and the second photoelectric conversion element.
(11)

The photodetector according to (9) or (10), in which the amplification circuit is configured to generate the voltage signal based on the first photocurrent while the transistor is in an off state, the first photocurrent being outputted by the first photoelectric conversion element.
(12)

The photodetector according to any one of (1) to (10), further including an optical element configured to output an optical signal.
(13)

The photodetector according to (12), in which

the optical element is configured to output the optical signal having a modulated frequency, and

the photoelectric conversion layer is configured to output a photocurrent by photoelectrically converting the optical signal reflected by an object.
(14)

The photodetector according to any one of (1) to (13), further including a memory circuit configured to hold a voltage signal based on the first photocurrent, the first photocurrent being outputted by the photoelectric conversion layer.
(15)

The photodetector according to (14), in which the readout circuit is configured to output the first signal based on the voltage signal, the voltage signal being held by the memory circuit.
(16)

The photodetector according to any one of (1) to (15), further including a semiconductor layer stacked on the photoelectric conversion layer, in which

the readout circuit and the AD conversion circuit are provided in the semiconductor layer.
(17)

An electronic apparatus including:

an optical system; and

a photodetector that receives light transmitted through the optical system, in which

the photodetector includes a plurality of pixel units, the plurality of pixel units each including

a photoelectric conversion layer configured to output a photocurrent by photoelectric conversion,

a readout circuit configured to output a first signal based on a first photocurrent, the first photocurrent being outputted by the photoelectric conversion layer, and

an AD conversion circuit configured to output a second signal based on a second photocurrent, the second photocurrent being outputted by the photoelectric conversion layer.

The present application claims the benefit of Japanese Priority Patent Application JP2023-051791 filed with the Japan Patent Office on Mar. 28, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A photodetector comprising a plurality of pixel units, the plurality of pixel units each including
a photoelectric conversion layer configured to output a photocurrent by photoelectric conversion,
a readout circuit configured to output a first signal based on a first photocurrent, the first photocurrent being outputted by the photoelectric conversion layer, and
an AD conversion circuit configured to output a second signal based on a second photocurrent, the second photocurrent being outputted by the photoelectric conversion layer.

2. The photodetector according to claim 1, wherein
the readout circuit is configured to output the first signal related to a gray scale value, and
the AD conversion circuit is configured to output the second signal related to a distance to an object.

3. The photodetector according to claim 1, wherein the pixel units each include a first amplification circuit and a second amplification circuit, the first amplification circuit being configured to generate a voltage signal based on the first photocurrent, the second amplification circuit being configured to generate a voltage signal based on the second photocurrent.

4. The photodetector according to claim 3, wherein
the readout circuit is configured to output the first signal based on the voltage signal generated by the first amplification circuit, and
the AD conversion circuit is configured to convert the voltage signal generated by the second amplification circuit into a digital signal, and to output the digital signal as the second signal.

5. The photodetector according to claim 3, wherein
the pixel units each include a first photoelectric conversion element and a second photoelectric conversion element, the first photoelectric conversion element and the second photoelectric conversion element being provided in the photoelectric conversion layer,
the first photoelectric conversion element and the second photoelectric conversion element are electrically coupled in series between a power supply line and a reference potential line, and
the second amplification circuit is configured to generate the voltage signal based on the second photocurrent, the second photocurrent being outputted by the first photoelectric conversion element and the second photoelectric conversion element.

6. The photodetector according to claim 3, wherein
the pixel units each include a third photoelectric conversion element provided in the photoelectric conversion layer, and
the first amplification circuit is configured to generate the voltage signal based on the first photocurrent outputted by the third photoelectric conversion element.

7. The photodetector according to claim 1, wherein the pixel units each include an amplification circuit, the amplification circuit being configured to generate a voltage signal based on the first photocurrent and a voltage signal based on the second photocurrent.

8. The photodetector according to claim 7, wherein
the readout circuit is configured to output the first signal on a basis of the voltage signal based on the first photocurrent, the first photocurrent being generated by the amplification circuit, and
the AD conversion circuit is configured to output the second signal on a basis of the voltage signal based on the second photocurrent, the second photocurrent being generated by the amplification circuit.

9. The photodetector according to claim 7, wherein
the pixel units each include a first photoelectric conversion element, a second photoelectric conversion element, and a transistor, the first photoelectric conversion element and the second photoelectric conversion element being provided in the photoelectric conversion layer, the transistor being coupled between the first photoelectric conversion element and the second photoelectric conversion element, and
the first photoelectric conversion element and the second photoelectric conversion element are electrically coupled in series between a power supply line and a reference potential line via the transistor.

10. The photodetector according to claim 9, wherein the amplification circuit is configured to generate the voltage signal based on the second photocurrent while the transistor is in an on state, the second photocurrent being outputted by the first photoelectric conversion element and the second photoelectric conversion element.

11. The photodetector according to claim 9, wherein the amplification circuit is configured to generate the voltage signal based on the first photocurrent while the transistor is in an off state, the first photocurrent being outputted by the first photoelectric conversion element.

12. The photodetector according to claim 1, further comprising an optical element configured to output an optical signal.

13. The photodetector according to claim 12, wherein
the optical element is configured to output the optical signal having a modulated frequency, and
the photoelectric conversion layer is configured to output a photocurrent by photoelectrically converting the optical signal reflected by an object.

14. The photodetector according to claim 1, further comprising a memory circuit configured to hold a voltage signal based on the first photocurrent, the first photocurrent being outputted by the photoelectric conversion layer.

15. The photodetector according to claim 14, wherein the readout circuit is configured to output the first signal based on the voltage signal, the voltage signal being held by the memory circuit.

16. The photodetector according to claim 1, further comprising a semiconductor layer stacked on the photoelectric conversion layer, wherein
the readout circuit and the AD conversion circuit are provided in the semiconductor layer.

17. An electronic apparatus comprising:
an optical system; and
a photodetector that receives light transmitted through the optical system, wherein
the photodetector includes a plurality of pixel units, the plurality of pixel units each including
a photoelectric conversion layer configured to output a photocurrent by photoelectric conversion,
a readout circuit configured to output a first signal based on a first photocurrent, the first photocurrent being outputted by the photoelectric conversion layer, and
an AD conversion circuit configured to output a second signal based on a second photocurrent, the second photocurrent being outputted by the photoelectric conversion layer.
